(19) United States
(12) Patent Application Publication
(10) Pub. No.: US 2026/0012174 A1
(43) Pub. Date: Jan. 8, 2026

(54) POWER ELECTRONICS DEVICE

(71) Applicant: Infineon Technologies Austria AG, Villach (AT)

(72) Inventor: Kennith Kin Leong, Villach (AT)

(21) Appl. No.: 18/765,850

(22) Filed: Jul. 8, 2024

(51) Int. Cl. H03K 17/691; H03K 17/732

(52) U.S. Cl. CPC H03K 17/691; H03K 17/732

(57) ABSTRACT

A power electronics device includes a voltage-driven transistor, a galvanically isolated gate driver and an energy storage device. The galvanically isolated gate driver is configured to receive a power signal, a turn-on signal, and a turn-off signal for the voltage-driven transistor over galvanic isolation implemented using a coreless transformer. The energy storage device is electrically connected to a gate of the voltage-driven power transistor and configured to store energy from the power signal received by the galvanically isolated gate driver and use the stored energy to stabilize a gate voltage of the voltage-driven power transistor during an on-state of the voltage-driven power transistor.

### BACKGROUND

Driving a GaN (gallium nitride) power transistor via a coreless transformer is typically implemented by using two coreless transformers to drive a single GaN power transistor. A particular type of normally-off GaN-based transistor, also referred to herein as a gate injection transistor (GIT), utilizes hole-injection from a p-AlGaN layer to an AlGaN/GaN heterojunction, which simultaneously increases electron density in the channel, to yield a dramatic increase in drain current due to conductivity modulation. The gate of GIT-type GaN power transistors effectively behave like a diode (i.e., current driven) and therefore a single coreless transformer coil can be used to deliver both power and driving signal information at the same time, by transmitting power to turn-on on the GIT-type GaN power transistor and stopping the power transmission to allow a failsafe pulldown device to self-turn-off. However, if the same single-core approach is applied to MOS gate-like structures (i.e., voltage driven) where the gate is voltage driven and not current driven, transmitting power and signal at the same time over the same coil is not known to be feasible.

Therefore, a new approach is needed to ensure correct turn-on and turn-off behavior and stable on-state gate voltage when driving voltage-driven transistors over a coreless transformer.

### SUMMARY

According to an embodiment of a power electronics device, the power electronics device comprises: a voltage-driven transistor; a galvanically isolated gate driver configured to receive a power signal, a turn-on signal, and a turn-off signal for the voltage-driven transistor over galvanic isolation implemented using a coreless transformer; and an energy storage device electrically connected to a gate of the voltage-driven power transistor and configured to store energy from the power signal received by the galvanically isolated gate driver and use the stored energy to stabilize a gate voltage of the voltage-driven power transistor during an on-state of the voltage-driven power transistor.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a circuit schematic of a power electronics device that includes a voltage-driven main transistor, a galvanically isolated gate driver, and an energy storage device, according to an embodiment.

FIGS. 2 through 5 illustrate operation of the power electronics device of FIG. 1 in different operating states.

FIG. 6 illustrates seven (7) different waveform plots during the different operating states shown in FIGS. 2 through 5.

FIG. 6 illustrates a circuit schematic of the power electronics device, according to another embodiment.

FIGS. 7 and 8 illustrate operation of the power electronics device 100 of FIG. 6 in different operating states.

FIG. 9 illustrates similar waveform plots as FIG. 5, but for the double receive-side coil configuration of FIG. 6.

FIG. 10 illustrates a circuit schematic of the power electronics device, according to another embodiment.

FIGS. 11 and 12 illustrate operation of the power electronics device of FIG. 10 in different operating states.

FIG. 13 illustrates similar waveform plots as FIG. 5, but for the single receive-side coil configuration of FIG. 10.

FIGS. 14 and 15 illustrate additional embodiments of the power electronics device.

### DETAILED DESCRIPTION

Embodiments described herein provide a power electronics device and related techniques for driving a voltage-driven transistor using a transformer. The embodiments utilize a local energy storage device such as a capacitor to stabilize the gate voltage during the on-state of the voltage-driven transistor, in conjunction with a failsafe technique that ensures reliable gate turn off. The phrase ‘voltage-driven transistor’ refers to a transistor having a MOS (metal-oxide-semiconductor) or Schottky barrier gate-like structure, as opposed to a current driven GIT-type GaN power transistor that utilizes hole-injection (current injection) from p-AlGaN to an AlGaN/GaN heterojunction.

Described next with reference to the figures are embodiments of the power electronics device and techniques for driving a voltage-driven transistor over a transformer.

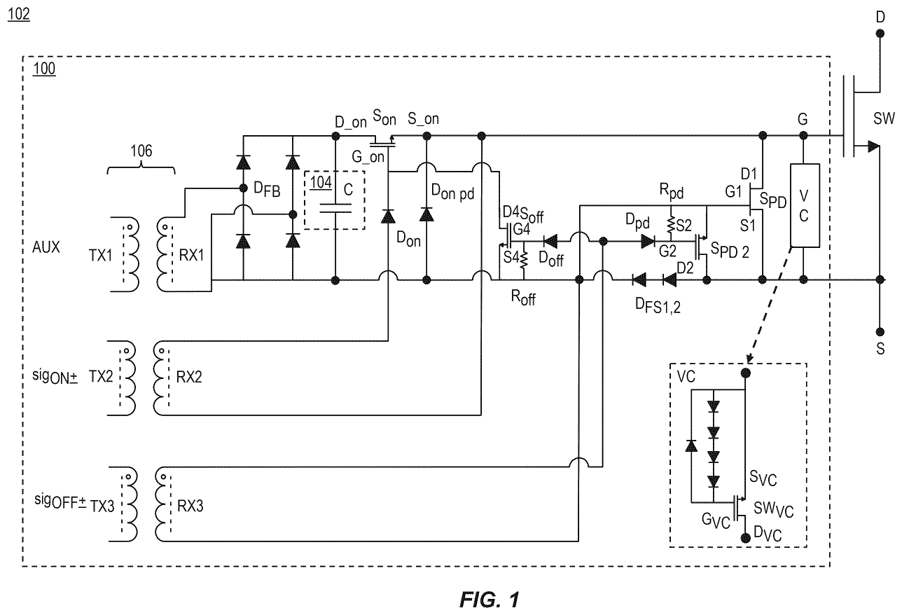

FIG. 1 illustrates a circuit schematic of an embodiment of a power electronics device 100. The power electronics device 100 includes a voltage-driven main transistor SW, a galvanically isolated gate driver 102, and an energy storage device 104. The main transistor SW is voltage driven in that the transistor SW has a MOS or Schottky barrier gate-like structure. For example, the voltage-driven main transistor SW may be a Si power MOSFET (metal-oxide-semiconductor field effect transistor) with a capacitive or Schottky gate or a GaN HEMT (high electron mobility transistor) with a capacitive or Schottky gate.

The galvanically isolated gate driver 102 receives a power signal AUX, a turn-on signal sig_{ON±}, and a turn-off signal sig_{OFF±} for the voltage-driven transistor SW over galvanic isolation 106. The energy storage device 104 is electrically connected to the gate G of the voltage-driven power transistor SW, and stores energy from the power received by the galvanically isolated gate driver 100. The energy stored by the energy storage device 104 is used to stabilize a gate voltage VGS of the voltage-driven power transistor SW in the on-state of the voltage-driven power transistor SW. In FIG. 1, the energy storage device 104 is implemented as a capacitor C coupled across the gate G and the source S of the voltage-driven power transistor SW.

The galvanically isolated gate driver 102 may also include a voltage clamp device VC electrically connected to the gate G of the voltage-driven power transistor SW. The voltage clamp device VC limits the gate voltage VGS of the voltage-driven power transistor SW, protecting the voltage-driven power transistor SW against overvoltage conditions. FIG. 1 illustrates an example of the voltage clamp device VC, which includes an n-channel transistor device SW_{VC} having a source S_{VC} connected to the gate G of the voltage-driven power transistor SW and a drain D_{VC} connected to the source S of the voltage-driven power transistor SW, a series of first diodes D_{VC1} connected between the source S_{VC} and the gate G_{VC} of the n-channel transistor device SW_{VC}, and at least one second diode D_{VC2} antiparallel to the series of first diodes D_{VC1}. Other types of voltage clamp devices may be used. The voltage clamp device VC may be omitted.

In FIG. 1, the galvanic isolation 106 is implemented using three pairs of transformer coils. The transformer coils may be implemented as a coreless transformer, for example. A ‘coreless transformer’ is a transformer that does not include a magnetic core. On the receive (RX) side of the galvanically isolated gate driver 102, the galvanically isolated gate driver 102 includes three (3) coils RX1, RX2, RX3. On the transmit (TX) side of the galvanically isolated gate driver 102, the galvanically isolated gate driver 102 includes three (3) corresponding coils TX1, TX2, TX3.

The first receive-side coil RX1 receives the power signal AUX for charging the energy storage device 104 over the galvanic isolation 106, from the first transmit-side coil TX1. The second receive-side coil RX2 receives the turn-on signal sig_{ON±} for the voltage-driven transistor SW over the galvanic isolation 106, from the second transmit-side coil TX2. The third receive-side coil RX3 receives the turn-off signal sig_{OFF±} for the voltage-driven transistor SW over the galvanic isolation 106, from the third transmit-side coil TX3.

The power electronics device 100 illustrated in FIG. 1 may be implemented using two (2) or more semiconductor dies (chips). For example, a silicon-based die may include the three (3) pairs of transformer coils TX1/RX1, TX2/RX2, TX3/RX3 and a GaN-based die may include the voltage-driven main transistor SW implemented, e.g., as a capacitive or Schottky gate GaN device. The GaN die can include an integrated capacitor (C) if the technology has the capability or the energy storage device 104 can be implemented as an external capacitor, either in the same package as the GaN die or connected outside of the package. Additional integration embodiments are described later herein.

In FIG. 1, the galvanically isolated gate driver 102 also includes a rectification circuit D_{FB} that rectifies the power signal AUX received at the first receive-side coil RX1, to energize the energy storage device 104 with the rectified power. The rectification circuit D_{FB} is shown as a full bridge diode rectifier in FIG. 1 but other types of rectifiers may be used, e.g., such as a half bridge diode rectifier or a synchronous (switched) rectifier.

An on/off switch device Sₒₙ of the galvanically isolated gate driver 102 is electrically connected between the energy storage device 104 and the gate G of the voltage-driven power transistor SW. A failsafe pulldown device S_{PD}, D_{FS1,2} is electrically connected to the gate G of the voltage-driven power transistor SW. The on/off switch device Sₒₙ connects the energy storage device 104 to the gate G of the voltage-driven power transistor SW when the turn-on signal sig_{ON±} received at the second receive-side coil RX2 is active.

In FIG. 1, a diode Don connects the upper end of the second receive-side coil RX2 to the gate G_on of the on/off switch device Sₒₙ. The anode of the diode Don is connected to the upper end of the second receive-side coil RX2 and the cathode of the diode Don is connected to the gate of the on/off switch device Sₒₙ. The source S_on of the on/off switch device Sₒₙ is electrically connected to the gate G of the voltage-driven power transistor SW. The drain D_on of the on/off switch device Sₒₙ is electrically connected to the energy storage device 104. The failsafe pulldown device S_{PD}, D_{FS1,2} pulls down the gate G of the voltage-driven power transistor SW when the turn-off signal sig_{OFF±} received at the third receive-side coil RX3 is active.

In FIG. 1, the failsafe pulldown device S_{PD}, D_{FS1,2} includes a normally-on pulldown device S_{PD} electrically connected between the gate G and the source S of the voltage-driven power transistor SW, and one or more diodes D_{FS1,2} electrically connected in series between the source S1 and the gate G1 of the normally-on pulldown device S_{PD}. The drain D1 of the normally-on pulldown device S_{PD} is electrically connected to the gate G of the voltage-driven power transistor SW.

In FIG. 1, the galvanically isolated gate driver 102 also includes a first normally-off pulldown device S_{PD2} electrically connected between the gate G1 and the source S1 of the normally-on pulldown device S_{PD}. The upper end of the third receive-side coil RX3 is electrically connected to the gate G2 of the first normally-off pulldown device S_{PD2} through one or more diodes D_{pd}. The lower end of the third receive-side coil RX3 is electrically connected to the gate G1 of the normally-on pulldown device S_{PD}. A resistor R_{pd} may be electrically connected between the gate G1 of the normally-on pulldown device S_{PD} and the gate G2 of the first normally-off pulldown device S_{PD2}. The source S2 of the first normally-off pulldown device S_{PD2} is electrically connected to the gate G1 of the normally-on pulldown device S_{PD}. The drain D2 of the first normally-off pulldown device S_{PD2} is electrically connected to the source S1 of the normally-on pulldown device S_{PD} and the source S of the voltage-driven power transistor SW.

In FIG. 1, the galvanically isolated gate driver 102 also includes a second normally-off pulldown device S_{off} electrically connected between the gate G_on of the on/off switch device Sₒₙ and the lower end of the third receive-side coil RX3. The upper end of the third receive-side coil RX3 is electrically connected to the gate S4 of the second normally-off pulldown device S_{off} through a diode D_{off}. A resistor R_{off} is electrically connected between the gate G4 and the source S4 of the second normally-off pulldown device S_{off}. The source S4 of the second normally-off pulldown device S_{off} is electrically connected to the opposite terminal of the energy storage device 104 as the drain D_on of the on/off switch device Sₒₙ. The drain D4 of the second normally-off pulldown device S_{off} is electrically connected to the gate G_on of the on/off switch device Sₒₙ.

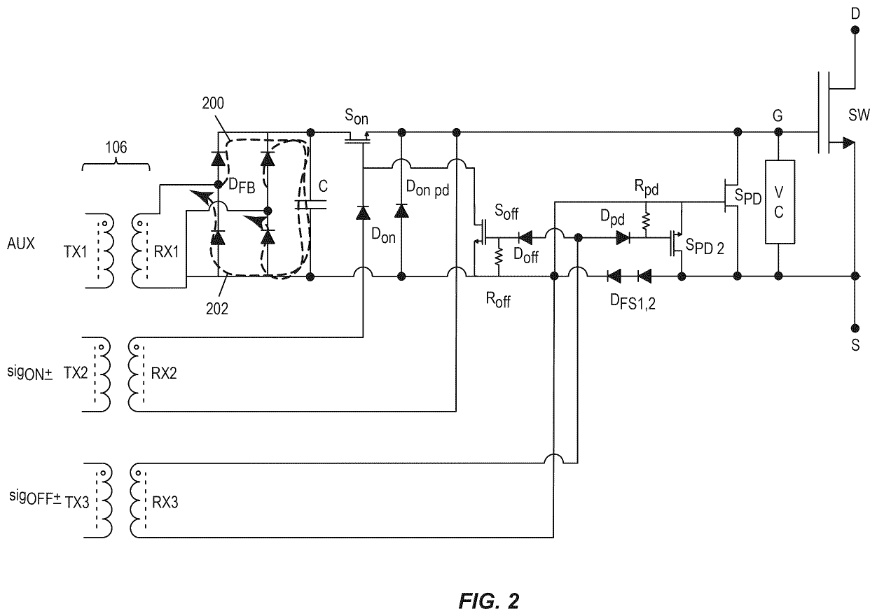

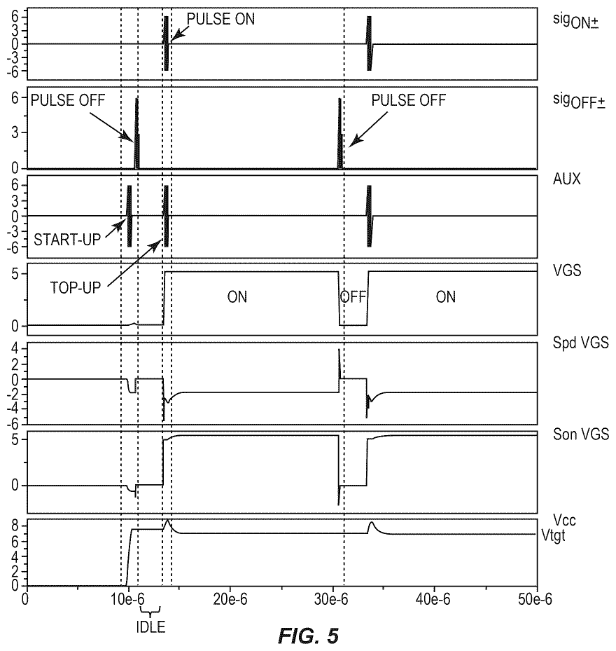

FIGS. 2 through 5 illustrate operation of the power electronics device embodiment of FIG. 1 in different operating states. FIG. 5 illustrates seven (7) different waveform plots during the different operating states shown in FIGS. 2 through 4. The upper three (3) plots show the on/off control and power signals sig_{ON±}, sig_{OFF±}, AUX, respectively, transmitted over the galvanic isolation 106. The fourth plot shows the gate-to-source voltage ‘VGS’ of the voltage-driven main transistor SW. The fifth plot shows the gate-to-source voltage ‘Spd VGS’ of the normally-on pulldown device S_{PD} of the failsafe pulldown device S_{PD}, D_{FS1,2}. The sixth plot shows the gate-to-source voltage ‘Son VGS’ of the on/off switch device Sₒₙ. The seventh plot shows the voltage ‘Vcc’ of the energy storage device 104.

FIG. 2 illustrates a charging state (‘Start-up’ in FIG. 5) of the power electronics device 100. In the charging state, energy is transferred from the first transmit-side coil TX1 to the first receive-side coil RX1 over the galvanic isolation 106 by activation of the power signal AUX. The energy received by the first receive-side coil RX1 flows into an auxiliary supply circuit formed by the rectification circuit D_{FB} and the energy storage device 104. During the positive part of the power signal AUX, energy flows from the upper end of the first receive-side coil RX1, into the energy storage device 104, and returns to the lower end of the first receive-side coil RX1 through one leg of the rectification circuit D_{FB}, as indicated by the first dashed line labelled 200 in FIG. 2. During the negative part of the power signal AUX, energy flows from the lower end of the first receive-side coil RX1, into the energy storage device 104, and returns to the upper end of the first receive-side coil RX1 through the other leg of the rectification circuit D_{FB}, as indicated by the second dashed line labelled 202 in FIG. 2. The rectification circuit D_{FB} rectifies the resulting AC waveform into a DC voltage Vcc for storing sufficient energy to subsequently drive the gate G of the voltage-driven main transistor SW. The bottom most plot of FIG. 5 shows the DC voltage Vcc rising to a target voltage level Vtgt during the charging state.

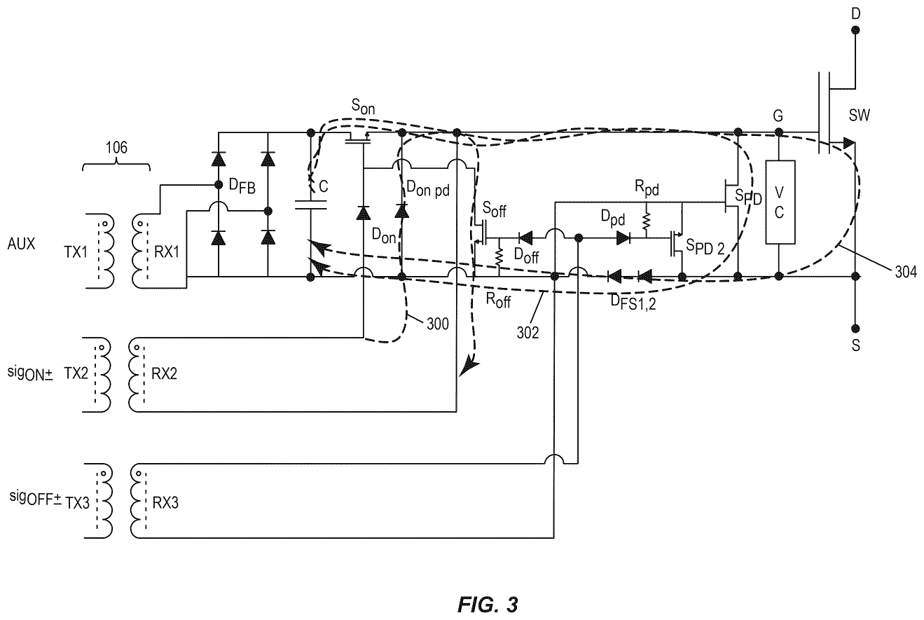

FIG. 3 illustrates an on state (‘ON’ in FIG. 5) of the power electronics device 100, during which the voltage-driven main transistor SW is on. To enter the on state, the turn-on signal sig_{ON±} is activated and transferred from the second transmit-side coil TX2 to the second receive-side coil RX2 over the galvanic isolation 106 (‘Pulse on’ in FIG. 5). The on/off switch device Sₒₙ is driven by the turn-on signal sig_{ON±} via a diode Don, as indicated by the first dashed line labelled 300 in FIG. 3. The diode Don stops the gate G_on of the on/off switch device Sₒₙ from discharging through the second receive-side coil RX1 when the second transmit-side coil TX1 is not transmitting, i.e., when the turn-on signal sig_{ON±} is inactive.

The default state of the normally-on pulldown device S_{PD} of the failsafe pulldown device S_{PD}, D_{FS1,2} is ON during no power conditions. Accordingly, the first normally-off pulldown device S_{PD2} is not required to turn the normally-on pulldown device S_{PD} back on. When the gate driver attempts to turn the voltage-driven main transistor SW on, the gate driver actively turns the normally-on pulldown device S_{PD} of the failsafe pulldown device S_{PD}, D_{FS1,2} off in that case. To turn the normally-on pulldown device S_{PD} of the failsafe pulldown device S_{PD}, D_{FS1,2} back on in this case, the first normally-off pulldown device S_{PD2} shorts the gate G1 and the source S1 of the normally-on pulldown device S_{PD}.

The voltage clamp of the failsafe pulldown device S_{PD}, D_{FS1,2} is shown as two diodes (D_{FS1,2}) with a diode threshold voltage (Vth), e.g., of 0.9V for a total clamp voltage of 1.8V in this example. The threshold voltage for the normally-on pulldown device S_{PD} may be designed to be around 0.9V, e.g., to give 50% margin to ensure the normally-on pulldown device S_{PD} remains off during the on state of the voltage-driven main transistor SW. When the on/off switch device Sₒₙ is on, the voltage Vcc of the energy storage device 104 is applied across diodes D_{FS1,2}, creating a voltage which turns the normally-on pulldown device S_{PD} off, as indicated by the second dashed line labelled 302 in FIG. 3. Once the normally-on pulldown device S_{PD} is off, the same voltage from the energy storage device 104 is applied across the gate G and source S of the voltage-driven main transistor SW and therefore turning the voltage-driven main transistor SW on, as indicated by the third dashed line labelled 304 in FIG. 3.

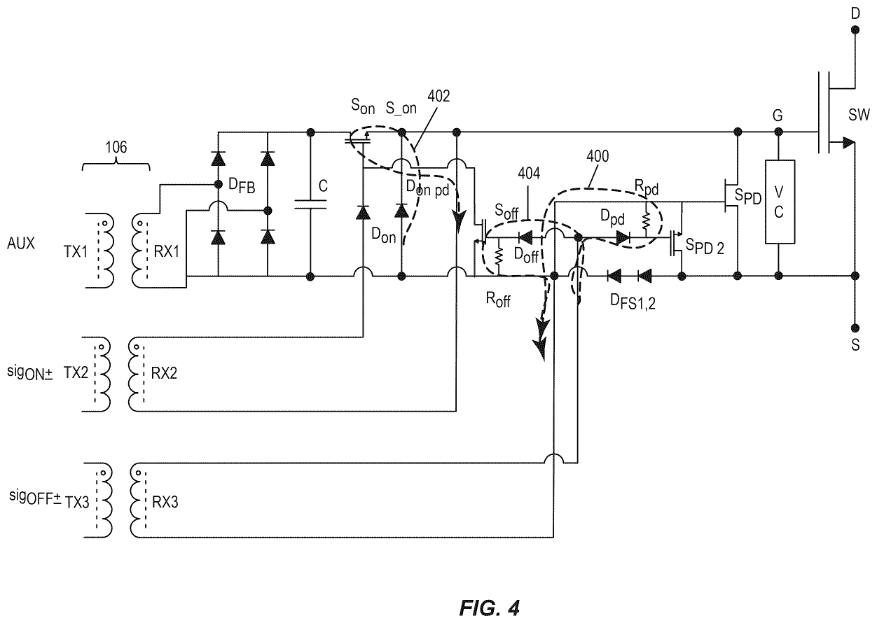

FIG. 4 illustrates an off state (‘OFF’ in FIG. 5) of the power electronics device 100, during which the voltage-driven main transistor SW is off. To enter the off state, the turn-off signal sig_{OFF±} is activated and transferred from the third transmit-side coil TX3 to the third receive-side coil RX3 over the galvanic isolation 106 (‘Pulse off’ in FIG. 5). In response to the activated turn-off signal sig_{OFF±}, the first normally-off pulldown device S_{PD2} of the galvanically isolated gate driver 102 turns off the voltage-driven main transistor SW by turning the normally-on pulldown device S_{PD} back on and the gate G2 of the first normally-off pulldown device S_{PD2} is driven via diode D_{pd} and discharges via resistor R_{pd}, as indicated by the first dashed line labelled 400 in FIG. 4. When the turn-off signal sig_{OFF±} is inactive, the first normally-off pulldown device S_{PD2} turns itself off. In parallel, the second normally-off pulldown device S_{off} of the galvanically isolated gate driver 102 discharges the gate G_on of the on/off switch device Sₒₙ via diode D_{onpd}, as indicated by the second dashed line labelled 402 in FIG. 4, and the gate G4 of the second normally-off pulldown device S_{off} is driven via diode D_{off} and discharges via resistor R_{off}, as indicated by the third dashed line labelled 404 in FIG. 4.

As demonstrated by the exemplary simulation shown in FIG. 5, control starts with a start-up sequence which transmits power through the first pair of coils TX1, RX1 to bring the voltage Vcc of the energy storage device up to a target level Vtgt of ˜7V in the illustrated example. A series of short pulses of the turn-off signal sig_{OFF±} ensures that the gate-to-source voltage ‘Spd VGS’ of the normally-on pulldown device S_{PD} of the failsafe pulldown device S_{PD}, D_{FS1,2} returns to zero voltage to stop the normally-on pulldown device S_{PD} from turning itself off. The control process then enters an idle mode (‘Idle’ in FIG. 5) where no signals are transmitted and the voltage-driven main transistor SW is off in a failsafe state. When the voltage-driven main transistor SW is to be turned on, the power signal AUX and the turn-on signal sig_{ON±} may be activated simultaneously to turn on the on/off switch device Sₒₙ and to top-up (‘Top-up’ in FIG. 5) voltage Vcc to maintain the voltage of the energy storage device 104 at a sufficiently high level for subsequently turning on the voltage-driven main transistor SW. During this time, the gate-to-source voltage ‘Spd VGS’ of the normally-on pulldown device S_{PD} discharges to −1.8V in this exemplary simulation, to ensure the normally-on pulldown device S_{PD} is in an off state and that the voltage-driven main transistor SW can be turned on and remain on. When the voltage-driven main transistor SW is to be turned off, the turn-off signal sig_{OFF±} is activated to turn off the voltage-driven main transistor SW by pulling down the gate-to-source voltage VGS of the voltage-driven main transistor SW and turning off the on/off switch device Sₒₙ to ensure that the voltage-driven main transistor SW remains off.

Since the power transfer coil pair TX1/RX1 is separate from the turn-on and turn-off signal transfer coil pairs TX2/RX2 and TX3/RX3, the top-up of voltage Vcc can also occur during ‘Pulse off’ phase, or any time during switching or idle mode. The top-up of voltage Vcc can be continuous or periodic, depending on technology requirements. In some cases, the voltage clamp circuit VC may be placed in parallel with the energy storage device 104 to protect the energy storage device 104 from over voltage conditions.

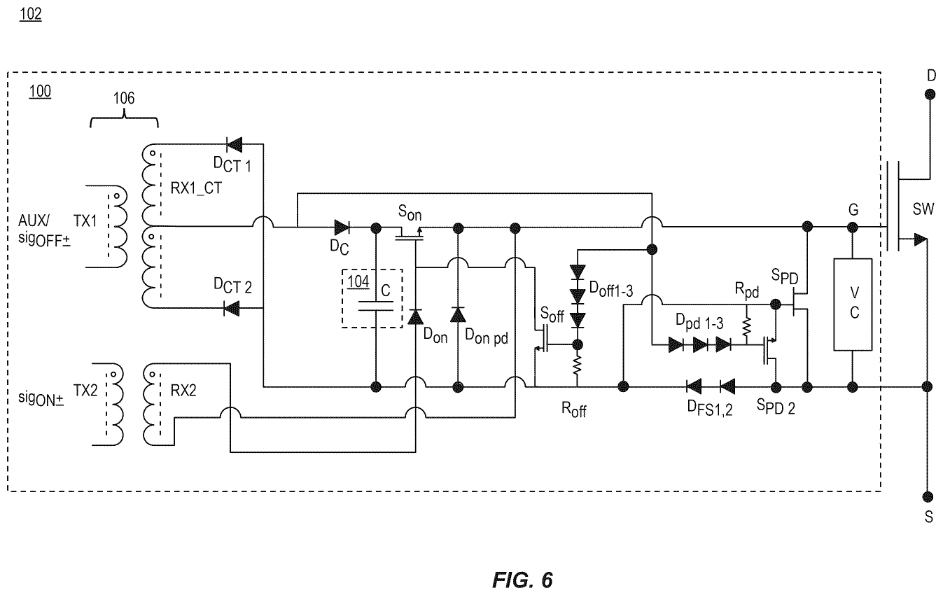

FIG. 6 illustrates a circuit schematic of another embodiment of the power electronics device 100. According to this embodiment, the galvanic isolation 106 is implemented using two pairs of transformer coils. The transformer coils may be implemented as a coreless transformer, for example. On the receive side of the galvanically isolated gate driver 102, the galvanically isolated gate driver 102 includes a center-tapped first coil RX1_CT and a second coil RX2. On the transmit side of the galvanically isolated gate driver 102, the galvanically isolated gate driver 102 includes two (2) corresponding coils TX1, TX2.

The center-tapped first receive-side coil RX1_CT receives the power signal AUX and the turn-off signal sig_{OFF±} for the voltage-driven transistor SW over the galvanic isolation 106, from the first transmit-side coil TX1. The second receive-side coil RX2 receives the turn-on signal sig_{ON±} for the voltage-driven transistor SW over the galvanic isolation 106, from the second transmit-side coil TX2. That is, the first coil pair TX1/RX1_CT is designed to simultaneously transmit the power signal AUX and the turn-off signal sig_{OFF±} for the voltage-driven transistor SW and the second coil pair TX2/RX2 is designed to transmit only the turn-on signal sig_{ON±} for the voltage-driven transistor SW.

The receive-side coil connections in FIG. 6 are described next in more detail. The upper end of the center-tapped first receive-side coil RX1_CT is electrically connected to the gate G1 of the normally-on pulldown device S_{PD} through one or more diodes D_{CT1}. The lower end of the center-tapped first receive-side coil RX1_CT is electrically connected to the gate G1 of the normally-on pulldown device S_{PD} through one or more diodes D_{CT2}. The center tap of the center-tapped first receive-side coil RX1_CT is electrically connected to the gate G2 of the first normally-off pulldown device S_{PD2} of the galvanically isolated gate driver 102 through one or more diodes D_{pd1-3}. The center tap of the center-tapped first receive-side coil RX1_CT is also electrically connected to the gate G4 of the second normally-off pulldown device S_{off} of the galvanically isolated gate driver 102 through one or more diodes D_{off1-3}. The center tap of the center-tapped first receive-side coil RX1_CT is also electrically connected to the drain D_on of the on/off switch device Sₒₙ of the galvanically isolated gate driver 102 through one or more diodes D_{C}. The second normally-off pulldown device S_{off} is electrically connected between the gate G_on of the on/off switch device Sₒₙ and the upper and lower ends of the center-tapped first receive-side coil RX1_CT. The upper end of the second receive-side coil RX2 is electrically connected to the gate G_on of the on/off switch device Sₒₙ through one or more diodes Dₒₙ. The lower end of the second receive-side coil RX2 is electrically connected to the gate G of the voltage-driven main power transistor SW. A resistor R_{pd} is electrically connected between the gate G1 of the normally-on pulldown device S_{PD} and the gate G2 of the first normally-off pulldown device S_{PD2}.

Compared to the embodiment in FIG. 1, the embodiment in FIG. 6 uses a center-tapped diode connection (D_{CT1,2}) compared to the rectification circuit D_{FB} in FIG. 1. Also, diode D_{C} in FIG. 6 prevents the capacitor C from discharging into resistor R_{PD} or resistor R_{OFF}. Furthermore, the turn-off signal sig_{OFF±} is tapped from the center-tapped first receive-side coil RX1_CT into the turn off circuitry, eliminating the need for a third pair of coils for transmitting the turn-off signal sig_{OFF±}.

The power electronics device 100 illustrated in FIG. 6 may be implemented using two (2) semiconductor dies. For example, a silicon-based die may include the two (2) pairs of transformer coils TX1/RX1_CT, TX2/RX2 and a GaN-based die may include the voltage-driven main transistor SW implemented, e.g., as a Schottky gate GaN device. The GaN die can include an integrated capacitor (C) if the technology has the capability or the energy storage device 104 can be implemented as an external capacitor, either in the same package as the GaN die or connected outside of the package. In another embodiment, the two (2) pairs of transformer coils TX1/RX1_CT, TX2/RX2 and the voltage-driven main transistor SW may be integrated on the same semiconductor die.

In FIG. 6, a rectification circuit D_{CT1}, D_{CT2}, D_{C} on the receive side of the galvanically isolated gate driver 102 rectifies the power signal AUX received at the center-tapped first receive-side coil RX1_CT and energizes the energy storage device 104 with the rectified power signal. The on/off switch device Sₒₙ of the galvanically isolated gate driver 102 connects the energy storage device 104 to the gate G of the voltage-driven main power transistor SW when the turn-on signal sig_{ON±} received at the second receive-side coil RX2 is active. The failsafe pulldown device S_{PD}, D_{FS1,2} of the galvanically isolated gate driver 102 pulls down the gate G of the voltage-driven main power transistor SW when the turn-off signal sig_{OFF±} received at the center-tapped first coil RX1_CT is active.

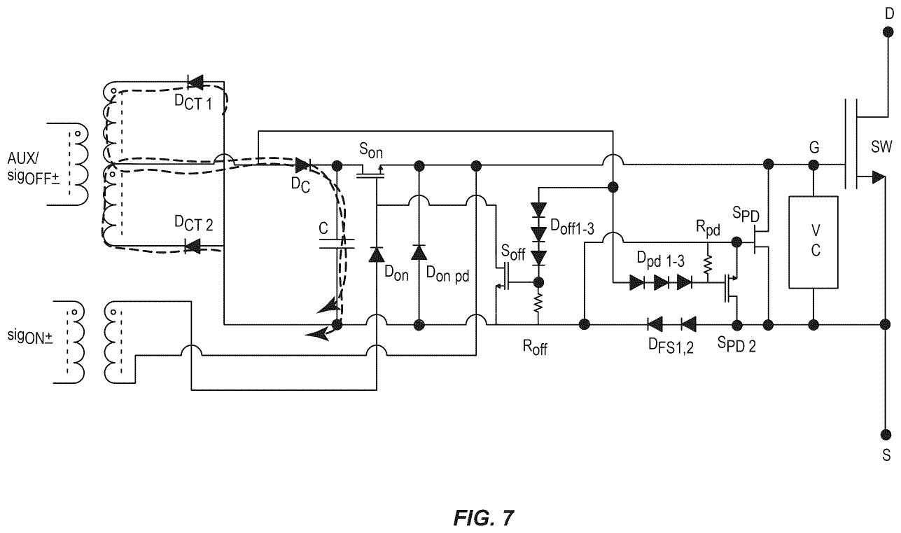

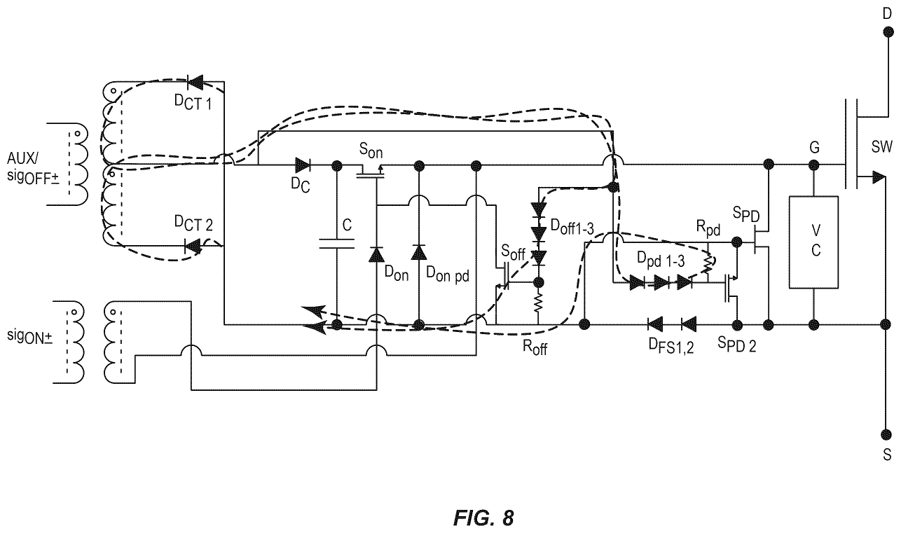

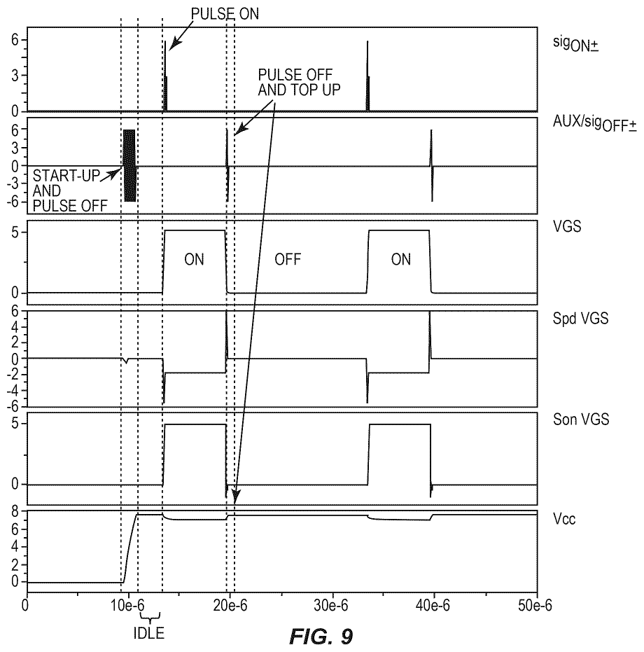

FIGS. 7 and 8 illustrate operation of the power electronics device 100 in FIG. 6 in different operating states. FIG. 9 illustrates similar waveform plots as FIG. 5, but for the double receive-side coil configuration of FIG. 6. Accordingly, FIG. 9 has one (1) less plot that FIG. 6 since power (energization) and turn-off control for the voltage-driven main power transistor SW is implemented using one coil pair TX1/RX1_CT in FIG. 6.

FIG. 7 illustrates the simultaneous charging and off state (‘Start-up and pulse off’ in FIG. 9). In the simultaneous charging and off state, the combined power and turn-off signal AUX/sig_{OFF±} is transmitted over the galvanic isolation 106 via the first coil pair TX1/RX1_CT. Since the turn-on signal sig_{ON±} is inactive in this state, the on/off switch device Sₒₙ of the galvanically isolated gate driver 102 remains off and the energy transferred from the first transmit-side coil TX1 to the center-tapped first receive-side coil RX1_CT over the galvanic isolation 106 flows into the auxiliary supply circuit formed by the rectification circuit D_{CT1}, D_{CT2} and the energy storage device 104. The dashed arrows in FIG. 7 indicate energy flow through the auxiliary supply circuit during the positive and negative parts of the combined power and turn-off signal AUX/sig_{OFF±}. The dashed arrows in FIG. 8 indicate the simultaneous (positive and negative) current direction to turn off the normally-on pulldown device S_{PD} and the second normally-off pulldown device S_{off} from the combined power and turn-off signal AUX/sig_{OFF±}. The turn on operation in FIG. 6, which is implemented over the second coil pair TX2/RX2, is the same as in FIG. 1.

As demonstrated by the exemplary simulation shown in FIG. 9, the control process starts with a start-up sequence which transmits power through the first coil pair TX1/RX1_CT to bring the voltage Vcc of the energy storage device 104 up to ˜7V in this example. Concurrently, the control process transmits turn-off pulses to ensure that the gate-to-source voltage ‘Spd VGS’ of the normally-on pulldown device S_{PD} returns to zero voltage to prevent the normally-on pulldown device S_{PD} from turning itself off. The control process then enters an idle mode (‘Idle’ in FIG. 9), where no signals are transmitted and the voltage-driven main transistor SW is off in a failsafe state. The control process turns on the voltage-driven main transistor by transmitting the turn-on signal sig_{ON±} over the second coil pair TX2/RX2 to turn on the on/off switch device Sₒₙ. In this example, and during this time, the gate-to-source voltage ‘Spd VGS’ of the normally-on pulldown device S_{PD} discharges to −1.8V to ensure that the normally-on pulldown device S_{PD} remains in the off state and that the voltage-driven main transistor SW can be turned on and remain on. To turn off the voltage-driven main transistor SW, the control process transmits turn-off signal pulses over the first coil pair TX1/RX1_CT to turn off the voltage-driven main transistor SW by pulling down the gate-to-source voltage ‘VGS’ of the voltage-driven main transistor SW and turning off the on/off switch device Sₒₙ to keep the voltage-driven main transistor SW in an off state. Concurrently, power can be transmitted (“pulse off and top up” in FIG. 9) to top-up the voltage Vcc of the energy storage device 104 and keep the voltage Vcc at a sufficiently high level. In this embodiment, the top up of the voltage of the energy storage device 104 occurs only during turn off or idle mode and during the on-state of the voltage-driven main transistor SW.

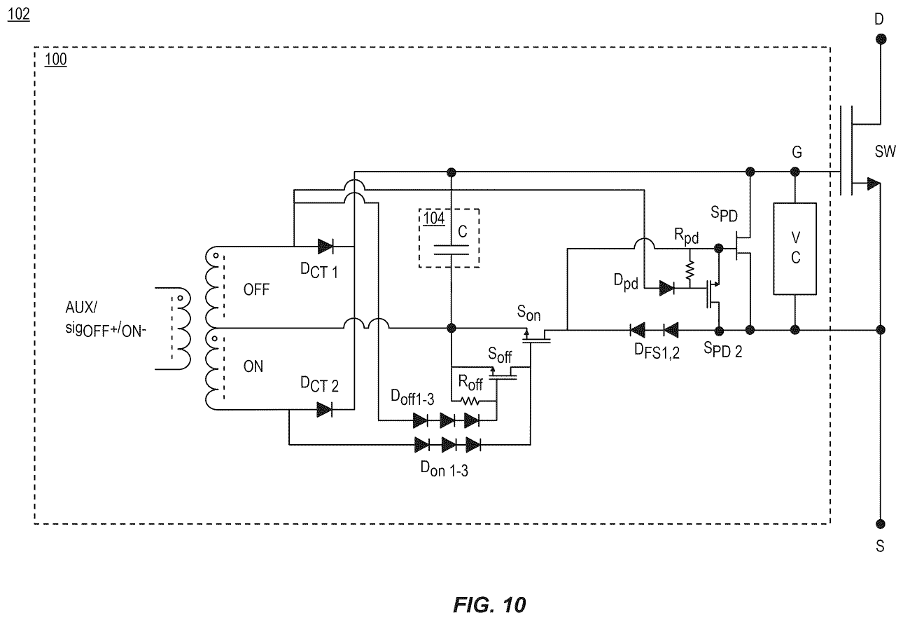

FIG. 10 illustrates a circuit schematic of another embodiment of the power electronics device 100. According to this embodiment, the galvanic isolation 106 is implemented using a single pair of transformer coils. The transformer coils may be implemented as a coreless transformer, for example. On the receive side of the galvanically isolated gate driver 102, the galvanically isolated gate driver 102 includes a single coil RX1_CT that is center-tapped. On the transmit side of the galvanically isolated gate driver 102, the galvanically isolated gate driver 102 includes a single coil TX1.

The center-tapped receive-side coil RX1_CT receives the power signal AUX, the turn-on signal sig_{ON±}, and the turn-off signal sig_{OFF±} for the voltage-driven transistor SW over the galvanic isolation 106, from the transmit-side coil TX1. That is, the coil pair TX1/RX1_CT is designed to simultaneously transmit the power signal AUX and the turn-off signal sig_{OFF±} for the voltage-driven transistor SW over one period of time and to transmit the turn-on signal sig_{ON±} for the voltage-driven transistor SW over a different period of time.

The power electronics device embodiment illustrated in FIG. 10 may be implemented using two (2) semiconductor dies. For example, a silicon-based die may include the single pair of transformer coils TX1/RX1_CT and a GaN-based die may include the voltage-driven main transistor SW implemented, e.g., as a Schottky gate GaN device. The GaN die can include an integrated capacitor (C) if the technology has the capability or the energy storage device 104 can be implemented as an external capacitor, either in the same package as the GaN die or connected outside of the package. In another embodiment, the single pair of transformer coils TX1/RX1_CT and the voltage-driven main transistor SW may be integrated on the same semiconductor die.

The receive-side coil connections in FIG. 10 are described next in more detail. The on/off switch device Sₒₙ is electrically connected between the energy storage device 104 and the source S of the voltage-driven main power transistor SW. The upper end the lower end of the center-tapped receive-side coil RX1_CT are electrically connected to the gate G of the voltage-driven main power transistor SW through the rectification circuit D_{CT1}, D_{CT2}. The lower end of the center-tapped receive-side coil RX1_CT is also electrically connected to the G_on gate of the on/off switch device Sₒₙ through one or more diodes Dₒₙ₁₋₃. The center tap of the center-tapped receive-side coil RX1_CT is electrically connected to the source S_on of the on/off switch device Sₒₙ. The normally-on pulldown device S_{PD} of the failsafe pulldown device is electrically connected to the gate G of the voltage-driven main power transistor SW. The first normally-off pulldown device S_{PD2} of the failsafe pulldown device is electrically connected between the gate G1 and the source S1 of the normally-on pulldown device S_{PD}, with one or more diodes D_{FS1,2} electrically connected in series between the source S1 and the gate G1 of the normally-on pulldown device S_{PD}. The drain D_on of the on/off switch device Sₒₙ is electrically connected to the gate G1 of the normally-on pulldown device S_{PD}. The source S of the voltage-driven main power transistor SW is electrically connected to the drain D_on of the on/off switch device Sₒₙ through the one or more diodes D_{FS1,2} electrically connected in series between the source S1 and the gate G1 of the normally-on pulldown device S_{PD}. The second normally-off pulldown device S_{off} of the galvanically isolated gate driver 102 is electrically connected between the gate G_on and the source S_on of the on/off switch device Sₒₙ. A resistor R_{off} is electrically connected between the gate G4 and the source S4 of the second normally-off pulldown device S_{off}. One or more diodes D_{off1-3} are electrically connected between the upper end of the center-tapped receive-side coil RX1_CT and the gate G4 of the second normally-off pulldown device S_{off}. A resistor R_{pd} is electrically connected between the gate G1 of the normally-on pulldown device S_{PD} and the gate G2 of the first normally-off pulldown device S_{PD2}.

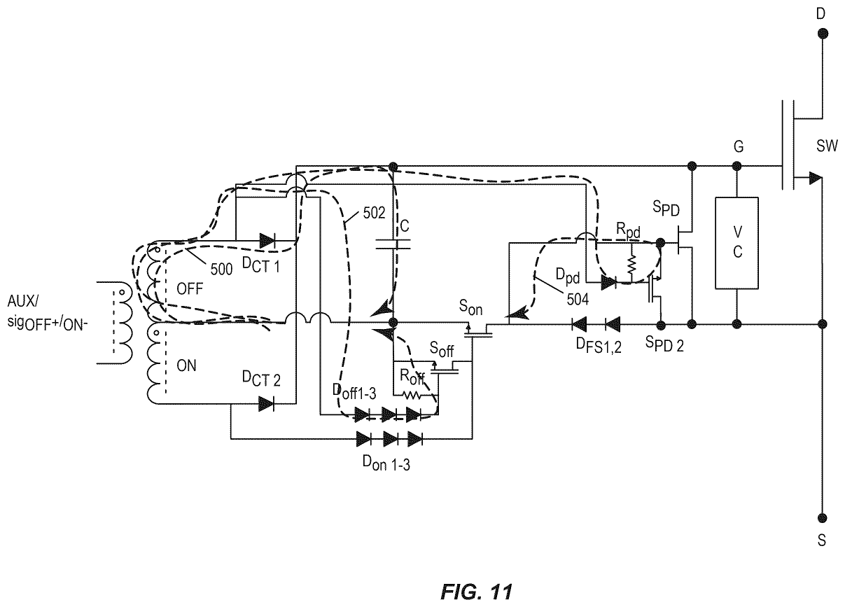

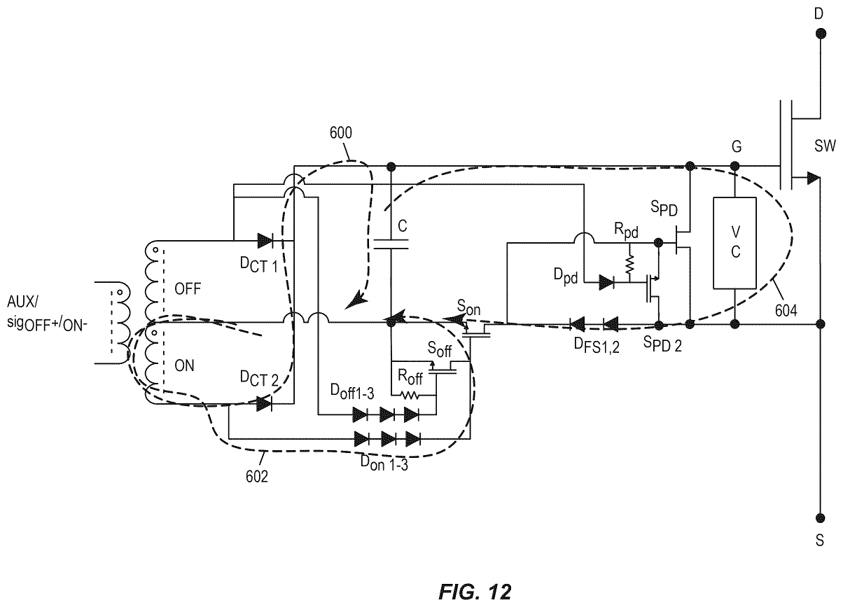

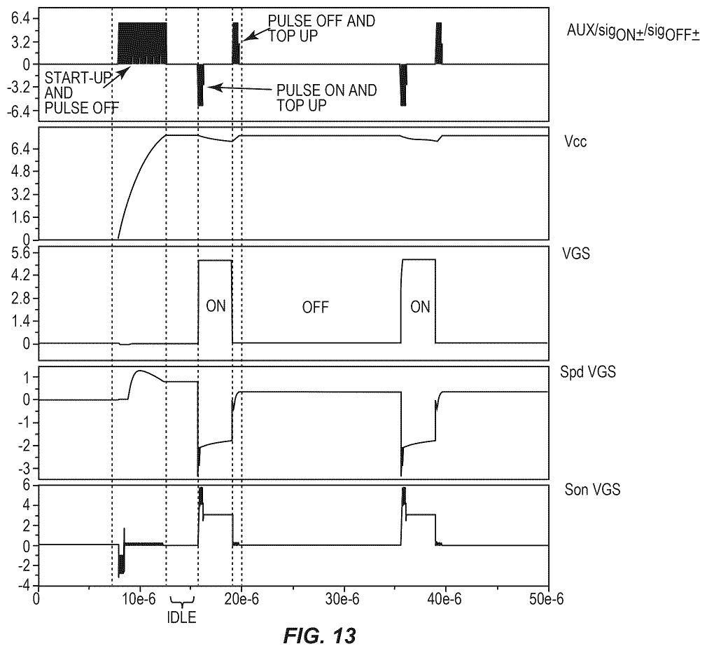

FIGS. 11 and 12 illustrate operation of the power electronics device 100 in FIG. 10 in different operating states. FIG. 13 illustrates similar waveform plots as FIG. 5, but for the single receive-side coil configuration of FIG. 10. Accordingly, FIG. 13 has two (2) less plots that FIG. 6 since power (energization), turn-on and turn-off control for the voltage-driven main power transistor SW is implemented using a single coil pair TX1/RX1_CT in FIG. 10.

The power electronics device embodiment illustrated in FIG. 10 is designed to transmit power and on/off switching signals at the same time, where the on and off switching control signals are distinguished based on the applied polarity of the input voltage on the transmit side of the galvanically isolated gate driver 102. To turn off the voltage-driven main transistor SW, only the upper part of the center-tapped receive-side coil RX1_CT is energized. The capacitor C charges via the loop indicated by the first dashed line labelled 500 in FIG. 11 (‘Pulse on and top up’ phase in FIG. 13). At the same time, pull down (turn off) of the on/off switch device Sₒₙ is enabled by turning on of the normally-on pulldown device S_{PD} by diode(s) D_{off1-3}, as indicated by the second dashed line labelled 502 in FIG. 11. Furthermore, the first normally-off pulldown device S_{PD2} is turned on via diode D_{pd}, as indicated by the third dashed line labelled 504 in FIG. 11. Safe start up is also enabled by the upper part of the center-tapped receive-side coil RX1_CT.

To turn off the voltage-driven main transistor SW, only the lower part of the center-tapped receive-side coil RX1_CT is energized. The lower part of the center-tapped receive-side coil RX1_CT is energized by negative pulses of the combined power and control signal AUX/sig_{ON±}/sig_{OFF±} (‘Start-up and pulse off’ phase in FIG. 13). The capacitor C charges via the loop indicated by the first dashed line labelled 600 in FIG. 12. At the same time, the on/off switch device Sₒₙ turns on via diode(s) Dₒₙ₁₋₃, as indicated by the second dashed line labelled 602 in FIG. 12. Once the on/off switch device Sₒₙ turns on, the gate G of the voltage-driven main transistor SW turns on via the failsafe pulldown device, as indicated by the third dashed line labelled 604 in FIG. 12.

As demonstrated by the exemplary simulation shown in FIG. 13, the control process initiates a start-up sequence which includes power transmission through positive signal pulses received at the upper part of the center-tapped receive-side coil RX1_CT, to bring the voltage Vcc on the capacitor C up to ˜7V in this example. The control process then enters an idle mode (‘Idle’ in FIG. 13), where no signal pulses are transmitted over the galvanic isolation 106 and the voltage-driven main transistor SW remains off in a failsafe state. To turn on the voltage-driven main transistor SW, the control process transmits negative signal pulses received at the lower part of the center-tapped receive-side coil RX1_CT to turn on the on/off switch device Sₒₙ. During this time, the gate-to-source voltage ‘Spd VGS’ of the normally-on pulldown device S_{PD} discharges to ˜−1.8V in this exemplary simulation, to ensure that the normally-on pulldown device S_{PD} remains off and the voltage-driven main transistor SW can be turned on and remain on. To turn off the voltage-driven main transistor SW, the control process transmits positive signal pulses received at the upper part of the center-tapped receive-side coil RX1_CT to turn pull down the gate-to-source voltage VGS of the voltage-driven main transistor SW and turn off the on/off switch device Sₒₙ to keep the voltage-driven main transistor SW in the off state. In both the turn-on state and the turn-off state, the control process concurrently transmits power (‘Pulse on and top up’ in the turn-on state and ‘Pulse off and top up’ in the turn-off state in FIG. 13) for topping up the voltage Vcc of the energy storage device 104 to a sufficiently high level. In this configuration, the top up of Vcc occurs in both turn on and turn off modes.

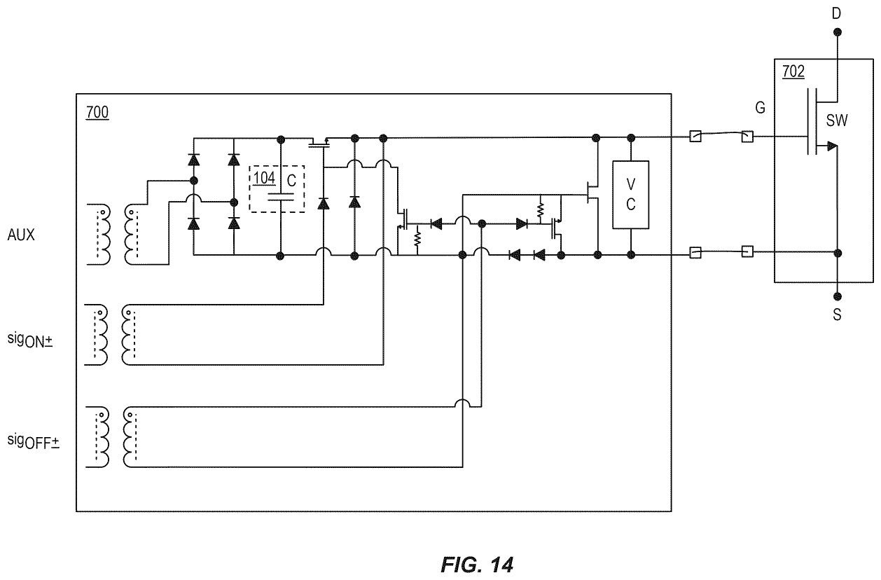

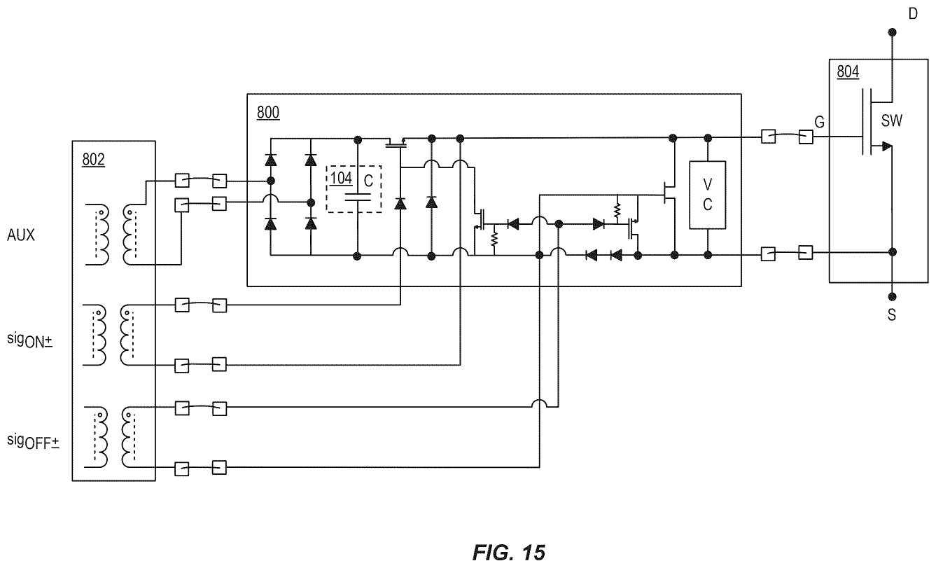

FIGS. 14 and 15 illustrate additional embodiments of the power electronics device 100. In FIGS. 14 and 15, the power electronics device 100 is shown with the triple receive-side coil configuration of FIG. 1 merely as an example. The embodiments of FIGS. 14 and 15 instead may be implemented with the double receive-side coil configuration of FIG. 6 or the single receive-side coil configuration of FIG. 10.

In FIG. 14, the rectification, on/off and failsafe circuitry of the galvanically isolated gate driver 102 is integrated on the same semiconductor die 700 as the transformer coils TXn/RXn. The voltage-driven main transistor SW is implemented on a separate (second) semiconductor die 702, e.g., a Si or GaN die, such that the voltage-driven main transistor SW can be any switch with a capacitive or Schottky gate. The energy storage device 104 may be integrated in one of the two (2) semiconductor dies 700, 702 or may be an external component, either in the same package as the dies 700, 702 or connected outside of the package.

In FIG. 15, the rectification, on/off and failsafe circuitry of the galvanically isolated gate driver 102 is included in a driver die 800 that is separate from the transformer die 802. The voltage-driven main transistor SW is implemented on a third semiconductor die 804, e.g., a Si or GaN die, such that the voltage-driven main transistor SW can be any switch with a capacitive or Schottky gate. The energy storage device 104 may be integrated in one of the three (3) semiconductor dies 800, 802, 804 or may be an external component, either in the same package as the dies 800, 802, 804 or connected outside of the package.

Although the present disclosure is not so limited, the following numbered examples demonstrate one or more aspects of the disclosure.

Example 1. A power electronics device, comprising: a voltage-driven transistor; a galvanically isolated gate driver configured to receive a power signal, a turn-on signal, and a turn-off signal for the voltage-driven transistor over galvanic isolation implemented using a coreless transformer; and an energy storage device electrically connected to a gate of the voltage-driven power transistor and configured to store energy from the power signal received by the galvanically isolated gate driver and use the stored energy to stabilize a gate voltage of the voltage-driven power transistor during an on-state of the voltage-driven power transistor.

Example 2. The power electronics device of example 1, wherein the galvanically isolated gate driver comprises: a voltage clamp device electrically connected to the gate of the voltage-driven power transistor.

Example 3. The power electronics device of example 1 or 2, wherein the galvanically isolated gate driver comprises: a first coil configured to receive the power signal over the galvanic isolation; a second coil configured to receive the turn-on signal over the galvanic isolation; and a third coil configured to receive the turn-off signal over the galvanic isolation.

Example 4. The power electronics device of example 3, wherein the galvanically isolated gate driver further comprises: a rectification circuit configured to rectify the power signal received at the first coil and energize the energy storage device with the rectified power signal; a first switch device electrically connected between the energy storage device and the gate of the voltage-driven power transistor; and a failsafe pulldown device electrically connected to the gate of the voltage-driven power transistor, wherein the first switch device is configured to connect the energy storage device to the gate of the voltage-driven power transistor when the turn-on signal received at the second coil is active, wherein the failsafe pulldown device is configured to pulldown the gate of the voltage-driven power transistor when the turn-off signal received at the third coil is active.

Example 5. The power electronics device of example 4, wherein the galvanically isolated gate driver further comprises: a diode having an anode connected to the second coil and a cathode connected to a gate of the first switch device.

Example 6. The power electronics device of example 4 or 5, wherein the failsafe pulldown device comprises a normally-on pulldown device electrically connected between the gate and a source of the voltage-driven power transistor, and one or more diodes electrically connected in series between a source and a gate of the normally-on pulldown device, wherein the galvanically isolated gate driver further comprises a first normally-off pulldown device electrically connected between the gate and the source of the normally-on pulldown device, wherein a first end of the third coil is electrically connected to a gate of the first normally-off pulldown device through one or more diodes, and a second end of the third coil is electrically connected to the gate of the normally-on pulldown device.

Example 7. The power electronics device of example 6, wherein the galvanically isolated gate driver further comprises: a second normally-off pulldown device electrically connected between a gate of the first switch device and the second end of the third coil, wherein the first end of the third coil is electrically connected to a gate of the second normally-off pulldown device through one or more diodes.

Example 8. The power electronics device of example 6 or 7, wherein the galvanically isolated gate driver further comprises: a resistor electrically connected between the gate of the normally-on pulldown device and the gate of the first normally-off pulldown device.

Example 9. The power electronics device of example 1 or 2, wherein the galvanically isolated gate driver comprises: a center-tapped first coil configured to receive the power signal and the turn-off signal over the galvanic isolation; and a second coil configured to receive the turn-on signal over the galvanic isolation.

Example 10. The power electronics device of example 9, wherein the galvanically isolated gate driver further comprises: a rectification circuit configured to rectify the power signal received at the first coil and energize the energy storage device with the rectified power signal; a first switch device electrically connected between the energy storage device and the gate of the voltage-driven power transistor; and a failsafe pulldown device electrically connected to the gate of the voltage-driven power transistor, wherein the first switch device is configured to connect the energy storage device to the gate of the voltage-driven power transistor when the turn-on signal received at the second coil is active, wherein the failsafe pulldown device is configured to pulldown the gate of the voltage-driven power transistor when the turn-off signal received at the first coil is active.

Example 11. The power electronics device of example 10, wherein the galvanically isolated gate driver further comprises: a diode having an anode connected to the second coil and a cathode connected to a gate of the first switch device.

Example 12. The power electronics device of example 10 or 11, wherein the failsafe pulldown device comprises a normally-on pulldown device electrically connected to the gate of the voltage-driven power transistor, and one or more diodes electrically connected in series between a source and a gate of the normally-on pulldown device, wherein the galvanically isolated gate driver further comprises a first normally-off pulldown device electrically connected between the gate and the source of the normally-on pulldown device, wherein a first end and a second end of the first coil are electrically connected to the gate of the normally-on pulldown device through one or more respective diodes, wherein the center tap of the first coil is electrically connected to a gate of the first normally-off pulldown device through one or more diodes.

Example 13. The power electronics device of example 12, wherein the galvanically isolated gate driver further comprises: a second normally-off pulldown device electrically connected between a gate of the first switch device and the first and second ends of the first coil, wherein the center tap of the first coil is electrically connected to a gate of the second normally-off pulldown device through one or more diodes, wherein a first end of the second coil is electrically connected to a gate of the first switch device through one or more diodes, wherein a second end of the second coil is electrically connected to the gate of the voltage-driven power transistor.

Example 14. The power electronics device of example 12 or 13, wherein the galvanically isolated gate driver further comprises: a resistor electrically connected between the gate of the normally-on pulldown device and the gate of the first normally-off pulldown device.

Example 15. The power electronics device of any of examples 10 through 14, wherein the center tap of the first coil is electrically connected to a drain of the first switch device through one or more diodes.

Example 16. The power electronics device of example 1 or 2, wherein the galvanically isolated gate driver comprises: a single center-tapped coil configured to receive the power signal, the turn-on signal, and the turn-off signal over the galvanic isolation.

Example 17. The power electronics device of example 16, wherein the galvanically isolated gate driver further comprises: a rectification circuit configured to rectify the power signal received at the center-tapped coil and energize the energy storage device with the rectified power signal; a first switch device electrically connected between the energy storage device and a source of the voltage-driven power transistor; and a failsafe pulldown device electrically connected to the gate of the voltage-driven power transistor, wherein a first end and a second end of the center-tapped coil are electrically connected to the gate of the voltage-driven power transistor through the rectification circuit, wherein the second end of the center-tapped coil is electrically connected to a gate of the first switch device through one or more diodes, wherein the center tap of the center-tapped coil is electrically connected to a source of the first switch device, wherein the failsafe pulldown device is configured to pulldown the gate of the voltage-driven power transistor when the turn-off signal received at the center-tapped coil is active.

Example 18. The power electronics device of example 17, wherein the failsafe pulldown device comprises: a normally-on pulldown device electrically connected to the gate of the voltage-driven power transistor; a first normally-off pulldown device electrically connected between a gate and a source of the normally-on pulldown device; and one or more diodes electrically connected in series between the source and the gate of the normally-on pulldown device, wherein a drain of the first switch device is electrically connected to the gate of the normally-on pulldown device, wherein the source of the voltage-driven power transistor is electrically connected to the drain of the first switch device through the one or more diodes electrically connected in series between the source and the gate of the normally-on pulldown device.

Example 19. The power electronics device of example 18, wherein the galvanically isolated gate driver further comprises: a second normally-off pulldown device electrically connected between the gate and the source of the first switch device; a resistor electrically connected between a gate and a source of the second normally-off pulldown device; and one or more diodes electrically connected between the first end of the center-tapped coil and the gate of the second normally-off pulldown device.

Example 20. The power electronics device of example 18 or 19, wherein the failsafe pulldown device further comprises: a resistor electrically connected between the gate of the normally-on pulldown device and a gate of the first normally-off pulldown device.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power electronics device, comprising:
a voltage-driven transistor;
a galvanically isolated gate driver configured to receive a power signal, a turn-on signal, and a turn-off signal for the voltage-driven transistor over galvanic isolation implemented using a coreless transformer; and
an energy storage device electrically connected to a gate of the voltage-driven power transistor and configured to store energy from the power signal received by the galvanically isolated gate driver and use the stored energy to stabilize a gate voltage of the voltage-driven power transistor during an on-state of the voltage-driven power transistor.

2. The power electronics device of claim 1, wherein the galvanically isolated gate driver comprises:
a voltage clamp device electrically connected to the gate of the voltage-driven power transistor.

3. The power electronics device of claim 1, wherein the galvanically isolated gate driver comprises:
a first coil configured to receive the power signal over the galvanic isolation;
a second coil configured to receive the turn-on signal over the galvanic isolation; and
a third coil configured to receive the turn-off signal over the galvanic isolation.

4. The power electronics device of claim 3, wherein the galvanically isolated gate driver further comprises:
a rectification circuit configured to rectify the power signal received at the first coil and energize the energy storage device with the rectified power signal;
a first switch device electrically connected between the energy storage device and the gate of the voltage-driven power transistor; and
a failsafe pulldown device electrically connected to the gate of the voltage-driven power transistor,
wherein the first switch device is configured to connect the energy storage device to the gate of the voltage-driven power transistor when the turn-on signal received at the second coil is active,
wherein the failsafe pulldown device is configured to pulldown the gate of the voltage-driven power transistor when the turn-off signal received at the third coil is active.

5. The power electronics device of claim 4, wherein the galvanically isolated gate driver further comprises:
a diode having an anode connected to the second coil and a cathode connected to a gate of the first switch device.

6. The power electronics device of claim 4,
wherein the failsafe pulldown device comprises a normally-on pulldown device electrically connected between the gate and a source of the voltage-driven power transistor, and one or more diodes electrically connected in series between a source and a gate of the normally-on pulldown device,
wherein the galvanically isolated gate driver further comprises a first normally-off pulldown device electrically connected between the gate and the source of the normally-on pulldown device,
wherein a first end of the third coil is electrically connected to a gate of the first normally-off pulldown device through one or more diodes, and a second end of the third coil is electrically connected to the gate of the normally-on pulldown device.

7. The power electronics device of claim 6, wherein the galvanically isolated gate driver further comprises:
a second normally-off pulldown device electrically connected between a gate of the first switch device and the second end of the third coil,
wherein the first end of the third coil is electrically connected to a gate of the second normally-off pulldown device through one or more diodes.

8. The power electronics device of claim 6, wherein the galvanically isolated gate driver further comprises:
a resistor electrically connected between the gate of the normally-on pulldown device and the gate of the first normally-off pulldown device.

9. The power electronics device of claim 1, wherein the galvanically isolated gate driver comprises:
a center-tapped first coil configured to receive the power signal and the turn-off signal over the galvanic isolation; and
a second coil configured to receive the turn-on signal over the galvanic isolation.

10. The power electronics device of claim 9, wherein the galvanically isolated gate driver further comprises:
a rectification circuit configured to rectify the power signal received at the first coil and energize the energy storage device with the rectified power signal;
a first switch device electrically connected between the energy storage device and the gate of the voltage-driven power transistor; and
a failsafe pulldown device electrically connected to the gate of the voltage-driven power transistor,
wherein the first switch device is configured to connect the energy storage device to the gate of the voltage-driven power transistor when the turn-on signal received at the second coil is active,
wherein the failsafe pulldown device is configured to pulldown the gate of the voltage-driven power transistor when the turn-off signal received at the first coil is active.

11. The power electronics device of claim 10, wherein the galvanically isolated gate driver further comprises:
a diode having an anode connected to the second coil and a cathode connected to a gate of the first switch device.

12. The power electronics device of claim 10,
wherein the failsafe pulldown device comprises a normally-on pulldown device electrically connected to the gate of the voltage-driven power transistor, and one or more diodes electrically connected in series between a source and a gate of the normally-on pulldown device,
wherein the galvanically isolated gate driver further comprises a first normally-off pulldown device electrically connected between the gate and the source of the normally-on pulldown device,
wherein a first end and a second end of the first coil are electrically connected to the gate of the normally-on pulldown device through one or more respective diodes,
wherein the center tap of the first coil is electrically connected to a gate of the first normally-off pulldown device through one or more diodes.

13. The power electronics device of claim 12, wherein the galvanically isolated gate driver further comprises:
a second normally-off pulldown device electrically connected between a gate of the first switch device and the first and second ends of the first coil,
wherein the center tap of the first coil is electrically connected to a gate of the second normally-off pulldown device through one or more diodes,
wherein a first end of the second coil is electrically connected to a gate of the first switch device through one or more diodes,
wherein a second end of the second coil is electrically connected to the gate of the voltage-driven power transistor.

14. The power electronics device of claim 12, wherein the galvanically isolated gate driver further comprises:
a resistor electrically connected between the gate of the normally-on pulldown device and the gate of the first normally-off pulldown device.

15. The power electronics device of claim 10, wherein the center tap of the first coil is electrically connected to a drain of the first switch device through one or more diodes.

16. The power electronics device of claim 1, wherein the galvanically isolated gate driver comprises:
a single center-tapped coil configured to receive the power signal, the turn-on signal, and the turn-off signal over the galvanic isolation.

17. The power electronics device of claim 16, wherein the galvanically isolated gate driver further comprises:
a rectification circuit configured to rectify the power signal received at the center-tapped coil and energize the energy storage device with the rectified power signal;
a first switch device electrically connected between the energy storage device and a source of the voltage-driven power transistor; and
a failsafe pulldown device electrically connected to the gate of the voltage-driven power transistor,
wherein a first end and a second end of the center-tapped coil are electrically connected to the gate of the voltage-driven power transistor through the rectification circuit,
wherein the second end of the center-tapped coil is electrically connected to a gate of the first switch device through one or more diodes,
wherein the center tap of the center-tapped coil is electrically connected to a source of the first switch device,
wherein the failsafe pulldown device is configured to pulldown the gate of the voltage-driven power transistor when the turn-off signal received at the center-tapped coil is active.

18. The power electronics device of claim 17, wherein the failsafe pulldown device comprises:
a normally-on pulldown device electrically connected to the gate of the voltage-driven power transistor;
a first normally-off pulldown device electrically connected between a gate and a source of the normally-on pulldown device; and
one or more diodes electrically connected in series between the source and the gate of the normally-on pulldown device,
wherein a drain of the first switch device is electrically connected to the gate of the normally-on pulldown device,
wherein the source of the voltage-driven power transistor is electrically connected to the drain of the first switch device through the one or more diodes electrically connected in series between the source and the gate of the normally-on pulldown device.

19. The power electronics device of claim 18, wherein the galvanically isolated gate driver further comprises:
a second normally-off pulldown device electrically connected between the gate and the source of the first switch device;
a resistor electrically connected between a gate and a source of the second normally-off pulldown device; and
one or more diodes electrically connected between the first end of the center-tapped coil and the gate of the second normally-off pulldown device.

20. The power electronics device of claim 18, wherein the failsafe pulldown device further comprises:
a resistor electrically connected between the gate of the normally-on pulldown device and a gate of the first normally-off pulldown device.
